(19) United States
(12) Patent Application Publication
(10) Pub. No.: US 2008/0185602 A1
(43) Pub. Date: Aug. 7, 2008

(54) Preparation of White Light Emitting Diode Using a Phosphor

(76) Inventors: Joung Kyu Park, Daejeon (KR); Chang Hae Kim, Daejeon (KR); Kyung Nam Kim, Daejeon (KR); Jae Myung Kim, Chungcheongnam-do (KR); Kyoung Jae Choi, Chungcheongnam-do (KR)

Correspondence Address: FROMMER LAWRENCE & HAUG, 745 FIFTH AVENUE- 10TH FL., NEW YORK, NY, 10151, US

(21) Appl. No.: 11/912,614

(22) PCT Filed: Apr. 25, 2006
(86) PCT No.: PCT/KR2006/001558

§ 371 Date: Oct. 25, 2007

(30) Foreign Application Priority Data
May 2, 2005 (KR) 10-2005-0036612

(51) Int. Cl. H01L 33/00

(52) U.S. Cl. 257/98; 438/27; 257/E33.061

(57) ABSTRACT

The present invention relates to a method for preparing a white light emitting diode (LED) using phosphors, especially to a white light emitting diode prepared by applying a tri-color phosphor material mixture of red, blue and green on a UV LED chip made of a packaging substrate, where white light is obtained by transmitting light through the tri-color phosphor mixture since the UV LED chip emits purple light. In particular, the present invention relates to a white light emitting diode prepared by laminating green and red or yellow and red phosphor materials on a blue LED chip, where white light is obtained as light is transmitted and absorbed by the phosphors. The method in accordance with the present invention is advantageous in that a white light emitting diode having superior photoluminescence efficiency can be provided using a single chip.

### TECHNICAL FIELD

The present invention relates to a method for preparing a white light emitting diode (LED) using phosphors, especially to a white light emitting diode prepared by applying a tri-color phosphor material mixture of red, blue and green on a UV LED chip made of a packaging substrate, in which white light is obtained by transmitting light through the tri-color phosphor mixture since the UV LED chip emits purple light.

In particular, the present invention relates to a white light emitting diode prepared by laminating green and red or yellow and red phosphor materials on a blue LED chip, in which white light is obtained as light is transmitted and absorbed by the phosphors.

### BACKGROUND ART

Light emitting diode has been spotlighted as natural color display device for future generation. It can be applied to a variety of electronic devices, including instrument panels, TVs and flat-panel displays.

Light emitting diode has the following phenomenon. When a phosphor material is subjected to an electric field, the electrons emitted at the cathode bind with the holes formed at the anode to form an excited state called ‘single excitons’. Various lights are emitted as they transit to the ground state. Light emitting diode is advantageous over the conventional photoluminescence devices with respect to photoluminescence efficiency, power consumption, thermal stability, durability and response.

Conventional methods for preparing a white light emitting diode are as follows.

Taiwanese Patent No. 383508 of Nichia, Japan discloses a method for preparing a white light emitting device using a blue light emitting chip and a yellow phosphor material (YAG).

The white light produced from blue and yellow lights only is suitable for displaying, but not adequate for lighting or backlight source of LCDs. In addition, because of the difficulty in controlling the amount of the yellow phosphor material, the white light tends to incline toward blue or yellow.

Korean Patent No. 0164457 (Sep. 12, 1998) discloses an EL (electroluminescent) device for attaining white light using Pr, a rare-earth element, as luminescent center, in which a white phosphor film having red, blue and green photoluminescence spectrum is laminated.

Korean Patent No. 0165867 (Sep. 19, 1998) discloses white light emitting electroluminescent device having superior photoluminescence spectrum distribution characteristics, which is prepared from a ZnS:Pr, Mn light emitting element.

Korean Patent Publication No. 2003-88882 (Nov. 20, 2003) discloses a white light emitting device in which white light is obtained by mixing the blue light from ZnS and the yellow from ZnSSe.

Although the above patents offer white light emitting devices, there is a need for the development of a white light emitting diode which is more superior and economical and is capable of offering better photoluminescence efficiency using a single chip and a preparation method thereof.

### DISCLOSURE OF THE INVENTION

The present invention aims at providing a white light emitting diode capable of solving the problems of conventional white LED and offering photoluminescence efficiency using a single chip and a method for preparing the same. An object of the present invention is to provide a method for preparing a white light emitting diode in which white light is obtained by applying a tri-color phosphor material mixture of red, blue and green on a UV LED chip made of a packaging substrate and transmitting the purple light emitted from the UV LED chip through the tri-color phosphor mixture or by laminating green and red or yellow and red phosphor materials on a blue LED chip and making the blue light emitted from the LED chip absorbed by the phosphor.

In an embodiment to attain the object, the present invention provides a method for preparing a white light emitting diode comprising a UV LED chip attached to the mount of a packaging substrate or a lead frame by Ag paste, an Au wire that connects the electrodes of the lead frame and the UV LED chip and transparent resin that encloses and protects the LED chip and the Au wire, in which tri-color phosphor materials of red, blue and green are applied directly or indirectly on the UV LED chip, so that white light can be obtained as the purple light emitted from the UV LED chip is transmitted through the tri-color phosphor material mixture.

In another embodiment, the present invention provides a method for preparing a white light emitting diode comprising a blue LED chip attached to the mount of a packaging substrate or a lead frame by Ag paste, Au wire that connects the electrodes of the lead frame and the LED chip and transparent resin that encloses and protects the LED chip and the Au wire, in which two-color phosphor materials of red and green or yellow and red are applied directly or indirectly on the blue LED chip, so that white light can be obtained as the blue light emitted from the blue LED chip is transmitted through the phosphor materials.

In a preferred embodiment, the UV LED chip and the blue LED chip emit light in the wavelength range of from 365 to 480 nm.

The red phosphor material is at least one selected from the group consisting of: a silicate-based Sr₃SiO₅:Eu phosphor; a sulfide-based phosphor in which Eu is used as active agent and the matrix has the formula (Srₓ, Ca_{y})S, where 0≦x23 1 and 0≦y≦1, typically SrS:Eu and CaS:Eu; and a SrY₂S₄:Eu phosphor.

The green phosphor material is at least one selected from the group consisting of: a silicate-based phosphor of the formula (Srₓ, Ba_{y}, Ca_{z})₂SiO₄:Eu, where 0≦x≦1, 0≦y23 1 and 0≦z23 1, typically Sr₂SiO₄:Eu, Ba₂SiO₄:Eu or Ca₂SiO₄:Eu; a thiogallate-based phosphor in which Eu is used as active agent and the matrix has the formula (Srₓ, Ba_{y}, Ca_{z})Ga₂S₄, where 0≦x≦1,0≦y≦1 and 0≦z≦1, typically SrGa₂S₄:Eu, BaGa₂S₄:Eu, CaGa₂S₄:Eu or Sr₂Ga₂S₅:Eu; and a thioaluminate-based phosphor of the formula (Srₓ, Ba_{y}, Ca_{z})Al₂S₄, where 0≦x≦1,0≦y≦1 and 0≦z≦1, typically SrAl₂S₄:Eu, BaAl₂S₄:Eu or Sr₂Al₂S₅:Eu.

The blue phosphor material is at least one selected from the group consisting of: a silicate-based phosphor of the formula (Srₓ, Ba_{y}, Ca_{z})₃MgSi₂O₈:Eu, where 0≦x≦1, 0≦y≦1 and 0≦z≦1, typically Sr₃MgSi₂O₈:Eu or Ba₃MgSi₂O₈:Eu; a sulfide-based phosphor in which Ce is used as active agent and the matrix has the formula (Srₓ, Ca_{y})S, where 0≦x≦1 and 0≦y≦1, typically SrS:Ce and CaS:Ce; and a CaAl₂S₄:Eu phosphor.

The red phosphor material, the green phosphor material and the blue phosphor material are mixed at a proportion of 1-2:1-2:1-3.

And, the red phosphor material and the green phosphor material are mixed at a proportion of 1-2:1-2.

Hereunder is given a more detailed description of the present invention.

In the present invention, white light is obtained by transmitting purple light or blue light through phosphor materials emitting different lights in the wavelength range of from 390 to 480 nm. This technique is different from one adding a yellow phosphor material (YAG) to a blue light emitting chip or transmitting UV light through a tri-color phosphor material to obtain white light.

As is well known, a light emitting diode comprises an LED chip (10) attached to the mount (concave part) of a packaging substrate (printed circuit board: PCB, ceramic substrate, silicon substrate, metal substrate, etc.) or a lead frame (60) by Ag paste (20), an Au wire (40) that connects the electrodes of the lead frame (60) and the LED chip (10) and a transparent resin (50) that encloses and protects the LED chip (10) and the Au wire (40).

In an embodiment of the present invention, a UV LED chip emitting purple light is used for the LED chip and a tri-color phosphor material mixture of red, blue and green is applied to the UV LED chip directly or indirectly.

That is, a tri-color phosphor material mixture of red, blue and green is applied to the UV LED chip emitting purple light, with light-transmitting epoxy resin or silicone resin as base.

White light is obtained as purple light, emitted from the UV LED chip, passes through the tri-color phosphor material mixture of red, blue and green.

The reason why purple light is used in the present invention is that the light in the wavelength range of from 390 to 410 nm gives a photoluminescence efficiency of 10 mW or better, which is higher than offered by currently-employed blue or UV light. Further, as will be described later in the examples, the UV light in the wavelength range of from 390 to 410 nm results in more uniform photoluminescence of the phosphor material (of red, blue and green).

In the present invention, a silicate-based or sulfide-based phosphor in which Eu is used as active agent is used for the red phosphor material, a silicate-based, thiogallate-based or thioaluminate-based phosphor in which Eu is used as active agent is used for the green phosphor material and a silicate-based or thioaluminate-based phosphor in which Eu is used as active agent or a sulfide-based phosphor in which Ce is used as active agent is used for the blue phosphor material.

More specifically, the red phosphor material is at least one selected from the group consisting of a silicate-based Sr₃SiO₅:Eu phosphor; a sulfide-based phosphor in which Eu is used as active agent and the matrix has the formula (Srₓ, Ca_{y})S, where 0≦x≦1 and 0≦y≦1, typically SrS:Eu and CaS:Eu; and a SrY₂S₄:Eu phosphor.

The green phosphor material is at least one selected from the group consisting of a silicate-based phosphor of the formula (Srₓ, Ba_{y}, Ca_{z})₂SiO₄:Eu, where 0≦x≦1, 0≦y≦1 and 0≦z≦1, typically Sr₂SiO₄:Eu, Ba₂SiO₄:Eu or Ca₂SiO₄:Eu; a thiogallate-based phosphor in which Eu is used as active agent and the matrix has the formula (Srₓ, Ba_{y}, Ca_{z})Ga₂S₄, where 0≦x≦1, 0≦y≦1 and 0≦z≦1, typically SrGa₂S₄:Eu, BaGa₂S₄:Eu, CaGa₂S₄:Eu or Sr₂Ga₂S₅:Eu; and a thioaluminate-based phosphor of the formula (Srₓ, Ba_{y}, Ca_{z})Al₂S₄, where 0≦x≦1,0≦y≦1 and 0≦z≦1, typically SrAl₂S₄:Eu, BaAl₂S₄:Eu or Sr₂Al₂S₅:Eu.

Further, the blue phosphor material is at least one selected from the group consisting of a silicate-based phosphor of the formula (Srₓ, Ba_{y}, Ca_{z})₃MgSi₂O₈:Eu, where 0≦x≦1, 0≦y≦1 and 0≦z≦1, typically Sr₃MgSi₂O₈:Eu or Ba₃MgSi₂O₈:Eu; a sulfide-based phosphor in which Ce is used as active agent and the matrix has the formula (Srₓ, Ca_{y})S, where 0≦x≦1 and 0≦y≦1, typically SrS:Ce, CaS:Ce or CaAl₂S₄:Eu.

The light emitted from the UV LED chip or the blue LED chip has a wavelength in the range of from 365 to 480 nm.

In addition, the red phosphor material, the green phosphor material and the blue phosphor material are mixed at a proportion of 1-2:1-2:1-3.

Outside this range, it is difficult to obtain a white color having a wanted color coordinate.

In another embodiment of the present invention, a blue LED chip emitting blue light is used and a two-color phosphor material mixture of red and green or yellow and red is applied to the blue LED chip directly or indirectly.

That is, a two-color phosphor material mixture of red and green is applied to the blue LED chip, with light-transmitting epoxy resin or silicone resin as base.

The red phosphor material and the green phosphor material are mixed at a proportion of 1-2:1-2. Outside this range, it is difficult to obtain a white light having a wanted color coordinate.

White light is obtained as the blue light emitted from the blue LED chip passes through the phosphor material mixture of red and green or yellow and red.

Of course, lights with a variety of color temperatures or colors can be obtained by varying the mixing proportion of the red, blue and green phosphors.

The tri-color phosphor material mixture of red, blue and green can offer a wanted white light by LTV light, while the two-color phosphor material mixture of red and green can offer a wanted white light by blue light.

Further, the white light may have a color temperature in the range of from 3,000 to 10,000 K, in order to satisfy the customer needs, by adjusting the mixing proportion of the red, blue and green phosphor materials.

Phosphor materials other than those mentioned above may be used in the present invention, as long as they absorb light in the wavelength range of from 365 to 480 nm and give light in the visible region.

Conventionally, only the UV light in the wavelength range of from 254 nm to 365 nm was utilized. But, in accordance with the present invention, it is possible to obtain white light using a tri-color or two-color phosphor mixture and using a UV LED chip emitting purple light or a blue LED chip emitting blue light.

In particular, it has become possible to supplement the weak red proportion which occurs when white light is obtained using a blue light emitting chip and a yellow phosphor.

### BRIEF DESCRIPTION OF THE DRAWINGS

FIG. 1 is a cross-sectional view of the package type white light emitting diode according to the present invention.

FIG. 2 is an enlarged cross-sectional view of the part where the LED is mounted in FIG. 1.

FIG. 3 shows the photoluminescence spectrum of the white light emitting diode prepared in Example 1 using a LED chip emitting 405 nm purple light and a phosphor mixture of blue, green and red.

FIG. 4 shows the photoluminescence spectrum of the white light emitting diode prepared in Example 2 using a LED chip emitting 465 nm blue light and a phosphor mixture of green and red.

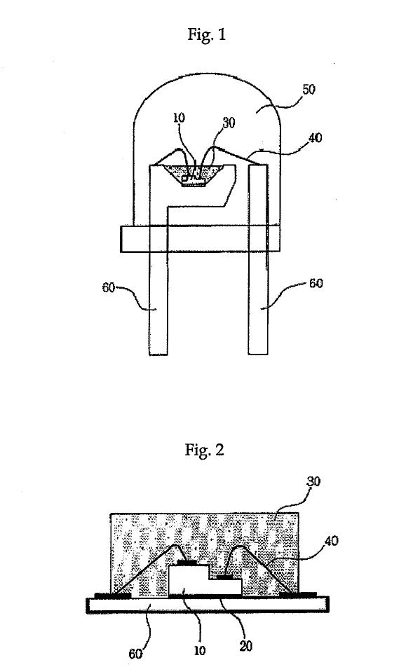

### BEST MODE FOR CARRYING OUT THE INVENTION

Practical and preferred embodiments of the present invention are illustrated as shown in the following examples. However, it will be appreciated that those skilled in the art may, in consideration of this disclosure, make modifications and improvements within the spirit and scope of the present invention.

### EXAMPLE 1

### Preparation of White Light Emitting Diode Using Phosphor of Red, Green and Blue

A UV LED chip was mounted on the mount of a packaging substrate or a lead frame using Ag paste. Subsequently, a tri-color phosphor material mixture of red, blue and green was applied on the UV LED chip directly or indirectly, so that the purple light emitted from the UV LED chip passed through the tri-color phosphor material mixture.

That is, each of the phosphor mixtures of red, blue and green given in Tables 1 to 3 below was applied on the UV LED chip, so that the 405 nm purple light emitted from the UV LED chip passed through the tri-color phosphor material mixture.

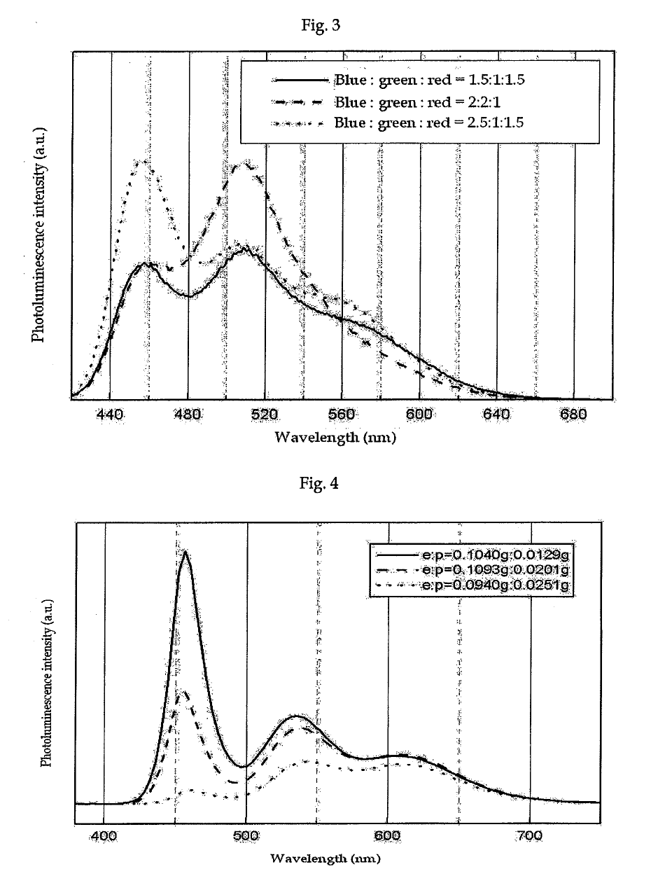

Production of white light was confirmed, as can be seen in the color coordinates given in Tables 1 to 3 and the photoluminescence spectrum given in FIG. 3.

TABLE 1

| | | | Mixing proportion | Color coordinate |
|---|---|---|---|---|
| Red phosphor | Green phosphor | Blue phosphor | (R:G:B) | (x, y) |
| Sr₃SiO₅:Eu | SrGa₂S₄:Eu | Sr₃MgSi₂O₈:Eu | 1:1:1 | 0.31, 0.30 |
| | | Ba₃MgSi₂O₈:Eu | 1:1:1 | 0.30, 0.29 |
| | | SrS:Ce | 1:1:2 | 0.41, 0.39 |
| | | CaS:Ce | 1:1:2 | 0.40, 0.42 |
| | | CaAl₂S₄:Eu | 1:1:3 | 0.41, 0.41 |
| | BaGa₂S₄:Eu | Sr₃MgSi₂O₈:Eu | 1:1:1 | 0.33, 0.30 |
| | | Ba₃MgSi₂O₈:Eu | 1:1:1 | 0.33, 0.29 |
| | | SrS:Ce | 1:1:2 | 0.42, 0.40 |
| | | CaS:Ce | 1:1:2 | 0.42, 0.41 |
| | | CaAl₂S₄:Eu | 1:1:3 | 0.41, 0.42 |
| | CaGa₂S₄:Eu | Sr₃MgSi₂O₈:Eu | 1:1:1 | 0.40, 0.30 |
| | | Ba₃MgSi₂O₈:Eu | 1:1:1 | 0.41, 0.29 |
| | | SrS:Ce | 1:1:2 | 0.40, 0.37 |
| | | CaS:Ce | 1:1:2 | 0.41, 0.35 |
| | | CaAl₂S₄:Eu | 1:1:3 | 0.42, 0.40 |
| | Sr₂Ga₂S₅:Eu | Sr₃MgSi₂O₈:Eu | 1:2:1 | 0.29, 0.29 |
| | | Ba₃MgSi₂O₈:Eu | 1:2:1 | 0.29, 0.31 |
| | | SrS:Ce | 1:2:2 | 0.35, 0.28 |
| | | CaS:Ce | 1:2:2 | 0.34, 0.27 |
| | | CaAl₂S₄:Eu | 1:2:3 | 0.36, 0.29 |
| | SrAl₂S₄:Eu | Sr₃MgSi₂O₈:Eu | 1:2:1 | 0.31, 0.29 |
| | | Ba₃MgSi₂O₈:Eu | 1:2:1 | 0.31, 0.31 |
| | | SrS:Ce | 1:2:2 | 0.37, 0.35 |
| | | CaS:Ce | 1:2:2 | 0.38, 0.38 |
| | | CaAl₂S₄:Eu | 1:2:3 | 0.40, 0.35 |
| | BaAl₂S₄:Eu | Sr₃MgSi₂O₈:Eu | 1:2:1 | 0.30, 0.33 |
| | | Ba₃MgSi₂O₈:Eu | 1:2:1 | 0.31, 0.32 |
| | | SrS:Ce | 1:2:2 | 0.36, 0.38 |
| | | CaS:Ce | 1:2:2 | 0.38, 0.37 |
| | | CaAl₂S₄:Eu | 1:2:3 | 0.39, 0.35 |
| | Sr₂Al₂S₅:Eu | Sr₃MgSi₂O₈:Eu | 1:2:1 | 0.31, 0.29 |
| | | Ba₃MgSi₂O₈:Eu | 1:2:1 | 0.31, 0.29 |
| | | SrS:Ce | 1:2:2 | 0.36, 0.35 |
| | | CaS:Ce | 1:2:2 | 0.39, 0.38 |
| | | CaAl₂S₄:Eu | 1:2:3 | 0.39, 0.36 |
| | Sr₂SiO₄:Eu | Sr₃MgSi₂O₈:Eu | 1:1:1 | 0.30, 0.30 |
| | | Ba₃MgSi₂O₈:Eu | 1:1:1 | 0.31, 0.30 |
| | | SrS:Ce | 1:1:2 | 0.37, 0.34 |
| | | CaS:Ce | 1:1:2 | 0.38, 0.34 |
| | | CaAl₂S₄:Eu | 1:1:3 | 0.39, 0.35 |
| | Ba₂SiO₄:Eu | Sr₃MgSi₂O₈:Eu | 1:1:1 | 0.30, 0.31 |
| | | Ba₃MgSi₂O₈:Eu | 1:1:1 | 0.31, 0.31 |
| | | SrS:Ce | 1:1:2 | 0.36, 0.32 |
| | | CaS:Ce | 1:1:2 | 0.35, 0.31 |
| | | CaAl₂S₄:Eu | 1:1:3 | 0.37, 0.32 |

TABLE 2

| | | | Mixing proportion | Color coordinate |
|---|---|---|---|---|
| Red phosphor | Green phosphor | Blue phosphor | (R:G:B) | (x, y) |
| SrS:Eu | SrGa₂S₄:Eu | Sr₃MgSi₂O₈:Eu | 1.5:1:1 | 0.30, 0.31 |
| | | Ba₃MgSi₂O₈:Eu | 1.5:1:1 | 0.31, 0.31 |
| | | SrS:Ce | 1.5:1:2 | 0.36, 0.31 |
| | | CaS:Ce | 1.5:1:2 | 0.38, 0.33 |
| | | CaAl₂S₄:Eu | 1.5:1:3 | 0.40, 0.35 |
| | BaGa₂S₄:Eu | Sr₃MgSi₂O₈:Eu | 1.5:1:1 | 0.29, 0.31 |
| | | Ba₃MgSi₂O₈:Eu | 1.5:1:1 | 0.30, 0.31 |
| | | SrS:Ce | 1.5:1:2 | 0.35, 0.32 |
| | | CaS:Ce | 1.5:1:2 | 0.37, 0.34 |
| | | CaAl₂S₄:Eu | 1.5:1:3 | 0.39, 0.37 |
| | CaGa₂S₄:Eu | Sr₃MgSi₂O₈:Eu | 1.5:1:1 | 0.33, 0.33 |
| | | Ba₃MgSi₂O₈:Eu | 1.5:1:1 | 0.33, 0.30 |
| | | SrS:Ce | 1.5:1:2 | 0.38, 0.33 |
| | | CaS:Ce | 1.5:1:2 | 0.39, 0.35 |
| | | CaAl₂S₄:Eu | 1.5:1:3 | 0.38, 0.37 |
| | Sr₂Ga₂S₅:Eu | Sr₃MgSi₂O₈:Eu | 1.5:2:1 | 0.32, 0.32 |
| | | Ba₃MgSi₂O₈:Eu | 1.5:2:1 | 0.33, 0.32 |
| | | SrS:Ce | 1.5:2:2 | 0.31, 0.36 |
| | | CaS:Ce | 1.5:2:2 | 0.33, 0.38 |
| | | CaAl₂S₄:Eu | 1.5:2:3 | 0.34, 0.38 |
| | SrAl₂S₄:Eu | Sr₃MgSi₂O₈:Eu | 1.5:2:1 | 0.27, 0.25 |
| | | Ba₃MgSi₂O₈:Eu | 1.5:2:1 | 0.30, 0.25 |
| | | SrS:Ce | 1.5:2:2 | 0.35, 0.30 |
| | | CaS:Ce | 1.5:2:2 | 0.36, 0.32 |
| | | CaAl₂S₄:Eu | 1.5:2:3 | 0.38, 0.35 |
| | BaAl₂S₄:Eu | Sr₃MgSi₂O₈:Eu | 1.5:2:1 | 0.25, 0.24 |
| | | Ba₃MgSi₂O₈:Eu | 1.5:2:1 | 0.23, 0.24 |
| | | SrS:Ce | 1.5:2:2 | 0.41, 0.37 |
| | | CaS:Ce | 1.5:2:2 | 0.40, 0.38 |
| | | CaAl₂S₄:Eu | 1.5:2:3 | 0.42, 0.39 |
| | Sr₂Al₂S₅:Eu | Sr₃MgSi₂O₈:Eu | 1.5:2:1 | 0.28, 0.26 |
| | | Ba₃MgSi₂O₈:Eu | 1.5:2:1 | 0.30, 0.27 |
| | | SrS:Ce | 1.5:2:2 | 0.35, 0.30 |
| | | CaS:Ce | 1.5:2:2 | 0.40, 0.37 |
| | | CaAl₂S₄:Eu | 1.5:2:3 | 0.39, 0.41 |
| | Sr₂SiO₄:Eu | Sr₃MgSi₂O₈:Eu | 1.5:1:1 | 0.31, 0.32 |
| | | Ba₃MgSi₂O₈:Eu | 1.5:1:1 | 0.30, 0.30 |
| | | SrS:Ce | 1.5:1:2 | 0.31, 0.38 |
| | | CaS:Ce | 1.5:1:2 | 0.34, 0.37 |
| | | CaAl₂S₄:Eu | 1.5:1:3 | 0.35, 0.40 |
| | Ba₂SiO₄:Eu | Sr₃MgSi₂O₈:Eu | 1.5:1:1 | 0.33, 0.31 |
| | | Ba₃MgSi₂O₈:Eu | 1.5:1:1 | 0.31, 0.29 |
| | | SrS:Ce | 1.5:1:2 | 0.35, 0.38 |
| | | CaS:Ce | 1.5:1:2 | 0.37, 0.40 |
| | | CaAl₂S₄:Eu | 1.5:1:3 | 0.37, 0.39 |

TABLE 3

| | | | Mixing proportion | Color coordinate |
|---|---|---|---|---|
| Red phosphor | Green phosphor | Blue phosphor | (R:G:B) | (x, y) |
| SrY₂S₄:Eu | SrGa₂S₄:Eu | Sr₃MgSi₂O₈:Eu | 2:1:1 | 0.29, 0.33 |
| | | Ba₃MgSi₂O₈:Eu | 2:1:1 | 0.27, 0.33 |
| | | SrS:Ce | 2:1:2 | 0.34, 0.37 |
| | | CaS:Ce | 2:1:2 | 0.35, 0.38 |
| | | CaAl₂S₄:Eu | 2:1:3 | 0.37, 0.35 |
| | BaGa₂S₄:Eu | Sr₃MgSi₂O₈:Eu | 2:1:1 | 0.30, 0.30 |
| | | Ba₃MgSi₂O₈:Eu | 2:1:1 | 0.31, 0.30 |
| | | SrS:Ce | 2:1:2 | 0.36, 0.35 |
| | | CaS:Ce | 2:1:2 | 0.38, 0.36 |
| | | CaAl₂S₄:Eu | 2:1:3 | 0.40, 0.35 |
| | CaGa₂S₄:Eu | Sr₃MgSi₂O₈:Eu | 2:1:1 | 0.38, 0.32 |
| | | Ba₃MgSi₂O₈:Eu | 2:1:1 | 0.36, 0.34 |
| | | SrS:Ce | 2:1:2 | 0.38, 0.40 |
| | | CaS:Ce | 2:1:2 | 0.38, 0.41 |
| | | CaAl₂S₄:Eu | 2:1:3 | 0.40, 0.43 |
| | Sr₂Ga₂S₅:Eu | Sr₃MgSi₂O₈:Eu | 2:2:1 | 0.33, 0.31 |
| | | Ba₃MgSi₂O₈:Eu | 2:2:1 | 0.34, 0.32 |
| | | SrS:Ce | 2:2:2 | 0.40, 0.37 |
| | | CaS:Ce | 2:2:2 | 0.40, 0.39 |
| | | CaAl₂S₄:Eu | 2:2:3 | 0.42, 0.41 |
| | SrAl₂S₄:Eu | Sr₃MgSi₂O₈:Eu | 2:2:1 | 0.28, 0.25 |
| | | Ba₃MgSi₂O₈:Eu | 2:2:1 | 0.30, 0.29 |
| | | SrS:Ce | 2:2:2 | 0.35, 0.30 |
| | | CaS:Ce | 2:2:2 | 0.37, 0.35 |
| | | CaAl₂S₄:Eu | 2:2:3 | 0.40, 0.36 |
| | BaAl₂S₄:Eu | Sr₃MgSi₂O₈:Eu | 2:2:1 | 0.30, 0.34 |
| | | Ba₃MgSi₂O₈:Eu | 2:2:1 | 0.31, 0.30 |
| | | SrS:Ce | 2:2:2 | 0.36, 0.33 |
| | | CaS:Ce | 2:2:2 | 0.37, 0.37 |
| | | CaAl₂S₄:Eu | 2:2:3 | 0.41, 0.39 |
| | Sr₂Al₂S₅:Eu | Sr₃MgSi₂O₈:Eu | 2:2:1 | 0.29, 0.27 |
| | | Ba₃MgSi₂O₈:Eu | 2:2:1 | 0.30, 0.29 |
| | | SrS:Ce | 2:2:2 | 0.33, 0.33 |
| | | CaS:Ce | 2:2:2 | 0.36, 0.37 |
| | | CaAl₂S₄:Eu | 2:2:3 | 0.41, 0.38 |
| | Sr₂SiO₄:Eu | Sr₃MgSi₂O₈:Eu | 2:1:1 | 0.29, 0.32 |
| | | Ba₃MgSi₂O₈:Eu | 2:1:1 | 0.31, 0.32 |
| | | SrS:Ce | 2:1:2 | 0.33, 0.37 |
| | | CaS:Ce | 2:1:2 | 0.33, 0.38 |
| | | CaAl₂S₄:Eu | 2:1:3 | 0.37, 0.40 |
| | Ba₂SiO₄:Eu | Sr₃MgSi₂O₈:Eu | 2:1:1 | 0.33, 0.32 |
| | | Ba₃MgSi₂O₈:Eu | 2:1:1 | 0.31, 0.33 |
| | | SrS:Ce | 2:1:2 | 0.35, 0.38 |
| | | CaS:Ce | 2:1:2 | 0.38, 0.39 |
| | | CaAl₂S₄:Eu | 2:1:3 | 0.40, 0.39 |

### EXAMPLE 2

### Preparation of White Light Emitting Diode Using Phosphor Mixture of Red and Green

A blue LED chip was mounted on the mount of a packaging substrate or a lead frame using Ag paste. Subsequently, a two-color phosphor material mixture of red and green was applied on the blue LED chip directly or indirectly, so that the blue light emitted from the blue LED chip passed through the two-color phosphor material mixture.

That is, each of the phosphor mixtures of red, blue and green given in Table 4 below was applied on the blue LED chip, so that the 465 nm blue light emitted from the blue LED chip passed through the two-color phosphor material mixture.

Production of white light was confirmed, as can be seen in the color coordinates given in Table 4 and the photoluminescence spectrum given in FIG. 4.

TABLE 4

| Red | | Mixing proportion | Color coordinate |
|---|---|---|---|
| phosphor | Green phosphor | (R:G) | (x, y) |
| Sr₃SiO₅:Eu | SrGa₂S₄:Eu | 1:1 | 0.33, 0.32 |
| | CaGa₂S₄:Eu | 1:1 | 0.35, 0.37 |
| | Sr₂Ga₂S₅:Eu | 1:2 | 0.32, 0.27 |
| | Sr₂SiO₄:Eu | 1:2 | 0.32, 0.32 |
| | Ba₂SiO₄:Eu | 1:3 | 0.31, 0.33 |
| SrS:Eu | SrGa₂S₄:Eu | 1:1 | 0.30, 0.31 |
| | CaGa₂S₄:Eu | 1:1 | 0.40, 0.35 |
| | Sr₂Ga₂S₅:Eu | 1:2 | 0.38, 0.34 |
| | Sr₂SiO₄:Eu | 1:1.5 | 0.31, 0.32 |
| | Ba₂SiO₄:Eu | 1:1.5 | 0.29, 0.33 |
| CaS:Eu | SrGa₂S₄:Eu | 1:1 | 0.30, 0.31 |
| | CaGa₂S₄:Eu | 1:1 | 0.35, 0.34 |
| | Sr₂Ga₂S₅:Eu | 1:2 | 0.33, 0.37 |
| | Sr₂SiO₄:Eu | 1:1.5 | 0.33, 0.32 |
| | Ba₂SiO₄:Eu | 1:1.5 | 0.31, 0.31 |
| SrY₂S₄:Eu | SrGa₂S₄:Eu | 2:1 | 0.31, 0.34 |
| | CaGa₂S₄:Eu | 2:1 | 0.35, 0.35 |
| | Sr₂Ga₂S₅:Eu | 1:1 | 0.30, 0.32 |
| | Sr₂SiO₄:Eu | 2:1.5 | 0.31, 0.31 |
| | Ba₂SiO₄:Eu | 2:1.5 | 0.29, 0.30 |

### INDUSTRIAL APPLICABILITY

As apparent from the above description, the white light emitting diode in accordance with the present invention can attain white light using a highly-efficient UV or blue LED chip and a phosphor material mixture of two or more colors, offering the best photoluminescence efficiency using a single chip.

Those skilled in the art will appreciate that the concepts and specific embodiments disclosed in the foregoing description may be readily utilized as a basis for modifying or designing other embodiments for carrying out the same purpose of the present invention. Those skilled in the art will also appreciate that such equivalent embodiments do not depart from the spirit and scope of the invention as set forth in the appended claims.

1. (canceled)

2. A method for preparing a white light emitting diode comprising a blue LED chip attached to the mount of a packaging substrate or a lead frame by Ag paste, a Au wire that connects the electrodes of the lead frame and the blue LED chip and a transparent resin that encloses and protects the LED chip and the Au wire, in which a two-color phosphor material mixture of red and green or yellow and red is applied to the blue LED chip directly or indirectly, so that white light is obtained as the blue light emitted from the blue LED chip passes through the two-color phosphor material mixture, where the blue LED chip emits light in the wavelength range of 450 to 480 nm.

3. (canceled)

4. The method for preparing a white light emitting diode as set forth in claim 2, wherein the red phosphor material is at least one selected from the group consisting of a silicate-based Sr3SiO5:Eu phosphor; a sulfide-based phosphor in which Eu is used as active agent and the matrix has the formula (Srx, Cay)S, where 0≦x≦1 and 0≦y≦1, typically SrS:Eu or CaS:Eu; and a SrY2S4:Eu phosphor.

5. The method for preparing a white light emitting diode as set forth in claim 2, wherein the green phosphor material is at least one selected from the group consisting of a silicate-based phosphor of the formula (Srx, Bay, Caz)2SiO4:Eu, where 0≦x≦1, 0≦y≦1 and 0≦z≦1, typically Sr2SiO4:Eu, Ba2SiO4:Eu or Ca2SiO4:Eu; a thiogallate-based phosphor in which Eu is used as active agent and the matrix has the formula (Srx, Bay, Caz)Ga2S4, where 0≦x≦1, 0≦y≦1 and 0≦z≦1, typically SrGa2S4:Eu, BaGa2:Eu, CaGa2S4:Eu or Sr2Ga2S5:Eu; and a thioaluminate-based phosphor of the formula (Srx, Bay, Caz)Al2S4, where 0≦x≦1, 0≦y≦1 and 0≦z≦1, typically SrAl2S4:Eu, BaAl2S4:Eu or Sr2Al2S5:Eu.

6. (canceled)

7. (canceled)

8. The method for preparing a white light emitting diode as set forth in claim 2, wherein the red phosphor material and the green phosphor material are mixed at a proportion of 1-2:1-2.

9. A lighting device comprising a white light emitting diode prepared by the method as set forth in claim 2.

10. A display device comprising a white light emitting diode prepared by the method as set forth in claim 2.

11. A backlight device comprising a white light emitting diode prepared by the method as set forth in claim 2.
